(19) United States
(12) Patent Application Publication
(10) Pub. No.: US 2026/0211073 A1
(43) Pub. Date: Jul. 23, 2026

(54) CALIBRATION DEVICE AND CALIBRATION METHOD FOR SIGNAL GENERATOR

(71) Applicant: ANRITSU CORPORATION, Kanagawa (JP)

(72) Inventors: Atsushi OSHIBA, Kanagawa (JP); Shinichi ITO, Kanagawa (JP)

(21) Appl. No.: 19/391,015

(22) Filed: Nov. 17, 2025

(30) Foreign Application Priority Data
Nov. 19, 2024 (JP) 2024-201680

(51) Int. Cl. G01R 35/00; G01R 23/02

(52) U.S. Cl. CPC G01R 35/005; G01R 23/02

(57) ABSTRACT

A calibration device for a signal generator includes a waveform data storage unit that outputs I waveform data and Q waveform data at an IF frequency to an I channel and a Q channel, respectively, a signal analysis unit that captures a modulated signal output from the quadrature modulator and quadrature-demodulates the modulated signal into I demodulated waveform data and Q demodulated waveform data at the IF frequency, an error calculation unit that calculates a difference in IF frequency-amplitude characteristics and a difference in IF frequency-phase characteristics, and an error correction unit that includes correction filters correcting the difference in IF frequency-amplitude characteristics between the I component and the Q component and the difference in IF frequency-phase characteristics between the I component and the Q component.

### TECHNICAL FIELD

The present invention relates to a calibration device and a calibration method for a signal generator.

### BACKGROUND ART

In order to develop or test wireless receivers, devices, and the like, the following is performed: a modulated signal is input from a signal generator to a device under test, and radio frequency (RF) characteristics and intermediate frequency (IF) characteristics of the device under test are measured; and it is checked whether or not the device under test has achieved desired characteristics.

In addition, in recent years, a bandwidth of a modulated signal has been widened in order to transmit high-speed data and the like.

In a signal generator using a quadrature modulator, an image signal is generated due to a difference in gain (difference in amplitude) between an I component and a Q component, a difference in delay (difference in phase) between the I component and the Q component, and a quadrature error of the quadrature modulator in a path from a digital-to-analog converter (D/A converter) to the quadrature modulator. When the image signal is generated, the measured value is more deteriorated than the actual value in, for example, error vector magnitude (EVM) measurement of the device under test. Therefore, it is desirable to minimize the amount of image signal generated.

### RELATED ART DOCUMENT

### Patent Document

[Patent Document 1] Japanese Patent No. 6209239

### DISCLOSURE OF THE INVENTION

### Problem that the Invention is to Solve

However, in the related art described in Patent Document 1, an image signal is reduced by measuring differences in gain and delay between an I component and a Q component at a certain IF frequency and causing a D/A converter to generate a signal such that the differences are compensated. That is, the IF frequency characteristics related to the differences in gain and delay between the I component and the Q component are considered to be flat, and the differences are measured and corrected at one IF frequency point.

In addition, since quadrature has no relation to the IF frequency, the quadrature is measured and corrected at an IF frequency of 0 Hz.

However, in recent years, as the bandwidth of the modulated signal has been widened, the IF frequency versus amplitude characteristics and the IF frequency versus phase characteristics are no longer considered to be flat. In correction with a correction value measured at one IF frequency point, the level of the image signal generated within a modulation output band is not capable of satisfying an image rejection ratio (IMRR) of, for example, 50 dB, which is a target value, and there is a concern that the reliability of the measurement result of the device under test may be reduced.

Here, the IMRR is defined as (power [dBm] of a desired CW signal)−(power [dBm] of a generated image signal). The smaller the generated image signal, the larger the IMRR.

The present invention has been made in order to solve the above-described problems, and an object of the present invention is to provide a calibration device and a calibration method for a signal generator that can reduce a level of an image signal generated within a quadrature modulation output band.

### Means for Solving the Problem

In order to achieve the above object, according to an aspect of the present invention, there is provided a calibration device (1) for a signal generator (10) including digital-to-analog (D/A) converters (11a, 11b) that perform D/A conversion on in-phase (I) waveform data and quadrature-phase (Q) waveform data, respectively, and a quadrature modulator (12) that quadrature-modulates signals subjected to the D/A conversion and outputs the signals as a modulated signal, the calibration device including: a waveform data storage unit (20) that outputs the I waveform data and the Q waveform data at an intermediate frequency (IF frequency) to an I channel and a Q channel, respectively; a signal analysis unit (40) that captures the modulated signal output from the quadrature modulator and quadrature-demodulates the captured modulated signal into I demodulated waveform data and Q demodulated waveform data at the IF frequency; an error calculation unit (50) that calculates a difference in IF frequency-amplitude characteristics between an I component and a Q component and a difference in IF frequency-phase characteristics between the I component and the Q component for the signal generator from the I demodulated waveform data and the Q demodulated waveform data acquired for a plurality of the IF frequencies; and an error correction unit (30) that is disposed between the waveform data storage unit and the D/A converters and includes correction filters (33a, 33b) correcting the difference in IF frequency-amplitude characteristics between the I component and the Q component and the difference in IF frequency-phase characteristics between the I component and the Q component.

As described above, the error calculation unit calculates the difference in IF frequency-amplitude characteristics between the I component and the Q component and the difference in IF frequency-phase characteristics between the I component and the Q component for the signal generator from the I demodulated waveform data and the Q demodulated waveform data acquired for the plurality of IF frequencies. Therefore, the error correction unit applies, for example, an inverse characteristic filter to the difference in IF frequency-amplitude characteristics between the I component and the Q component and the difference in IF frequency-phase characteristics between the I component and the Q component to correct the differences. This configuration makes it possible to appropriately correct the difference in IF frequency-amplitude characteristics between the I component and the Q component and the difference in IF frequency-phase characteristics between the I component and the Q component, which are factors of an image signal in signal paths from the D/A converters to the quadrature modulator, over the entire IF frequency range and thus to reduce the level of the image signal generated within a quadrature modulation output band.

In the calibration device according to the aspect of the present invention, the waveform data storage unit may alternately output a multi-tone signal obtained by combining two or more tone signals having different IF frequencies to the I channel and the Q channel and, while outputting the multi-tone signal to one of the I channel and the Q channel, may not output any signal to the other of the I channel and the Q channel, and the signal analysis unit may capture the modulated signal output from the quadrature modulator and quadrature-demodulate the captured modulated signal for each of the IF frequencies of the tone signals.

In this configuration, since a single-phase multi-tone signal is used as the calibration waveform data, it is possible to rapidly and accurately measure the amplitude and IF frequency-phase characteristics for each of the I channel and the Q channel.

In the calibration device according to the aspect of the present invention, the error calculation unit may calculate an IQ quadrature error, and the error correction unit may include a quadrature correction unit (32) that corrects the IQ quadrature error for the I waveform data and the Q waveform data output from the waveform data storage unit.

This configuration makes it possible to appropriately correct the IQ quadrature error which is a factor of the image signal in the quadrature modulator and thus to reduce the level of the image signal generated within the quadrature modulation output band.

The calibration device according to the aspect of the present invention may further include a correction value calculation unit that defines the calculated IQ quadrature error as α [rad] and calculates a first correction value A and a second correction value B used in the quadrature correction unit as A=cos α/cos 2α and B=−tan α, respectively. The quadrature correction unit may include a first multiplier (34a) that multiplies the I waveform data by the first correction value A, a second multiplier (34b) that multiplies the Q waveform data by the first correction value A, a third multiplier (34c) that multiplies a multiplication result of the second multiplier by the second correction value B, a fourth multiplier (34d) that multiplies a multiplication result of the first multiplier by the second correction value B, a first adder (35a) that adds the multiplication result of the first multiplier and the multiplication result of the third multiplier and outputs an addition result as corrected I waveform data, and a second adder (35b) that adds the multiplication result of the second multiplier and the multiplication result of the fourth multiplier and outputs an addition result as corrected Q waveform data.

This configuration makes it possible to appropriately correct the IQ quadrature error which is a factor of the image signal in the quadrature modulator and thus to reduce the level of the image signal generated within the quadrature modulation output band.

The calibration device according to the aspect of the present invention may further include a control unit (70). The error calculation unit may calculate an IQ gain balance, and the control unit may control the waveform data storage unit, the signal analysis unit, the error calculation unit, and the error correction unit such that the difference in IF frequency-amplitude characteristics between the I component and the Q component and the difference in IF frequency-phase characteristics between the I component and the Q component are corrected, and then cause those units to perform fine-tuning correction of the IQ quadrature error and the IQ gain balance while the signal analysis unit is measuring a level of an image signal.

In this configuration, the difference in IF frequency-amplitude characteristics between the I component and the Q component and the difference in IF frequency-phase characteristics between the I component and the Q component are appropriately corrected over the entire IF frequency range (coarse adjustment), and then the fine-tuning correction of the IQ quadrature error and the IQ gain balance is performed while the level of the image signal is being measured. Therefore, it is possible to rapidly set the IQ quadrature error and the IQ gain balance to optimal values.

In order to achieve the above object, according to another aspect of the present invention, there is provided a calibration method for a signal generator (10) including digital-to-analog (D/A) converters (11a, 11b) that perform D/A conversion on in-phase (I) waveform data and quadrature-phase (Q) waveform data, respectively, and a quadrature modulator (12) that quadrature-modulates signals subjected to the D/A conversion and outputs the signals as a modulated signal, the calibration method including: a waveform data output step of outputting the I waveform data and the Q waveform data at an intermediate frequency (IF frequency) to an I channel and a Q channel, respectively; a signal analysis step of capturing the modulated signal output from the quadrature modulator and quadrature-demodulating the captured modulated signal into I demodulated waveform data and Q demodulated waveform data at the IF frequency; an error calculation step of calculating a difference in IF frequency-amplitude characteristics between an I component and a Q component and a difference in IF frequency-phase characteristics between the I component and the Q component for the signal generator from the I demodulated waveform data and the Q demodulated waveform data acquired for a plurality of the IF frequencies; and an error correction step of being executed between the waveform data output step and the D/A conversion by the D/A converter and correcting the difference in IF frequency-amplitude characteristics between the I component and the Q component and the difference in IF frequency-phase characteristics between the I component and the Q component, using correction filters.

This configuration makes it possible to appropriately correct the difference in IF frequency-amplitude characteristics between the I component and the Q component and the difference in IF frequency-phase characteristics between the I component and the Q component, which are factors of an image signal in signal paths from the D/A converters to the quadrature modulator, over the entire IF frequency range and thus to reduce the level of the image signal generated within a quadrature modulation output band.

In the calibration method according to the aspect of the present invention, in the waveform data output step, a multi-tone signal obtained by combining two or more tone signals having different IF frequencies may be alternately output to the I channel and the Q channel, and, while the multi-tone signal is being output to one of the I channel and the Q channel, no signal may be output to the other of the I channel and the Q channel. In the signal analysis step, the modulated signal output from the quadrature modulator may be captured, and the captured modulated signal may be quadrature-demodulated for each of the IF frequencies of the tone signals.

In this configuration, since a single-phase multi-tone signal is used as the calibration waveform data, it is possible to rapidly and accurately measure the amplitude and IF frequency-phase characteristics for each of the I channel and the Q channel.

In the calibration method according to the aspect of the present invention, in the error calculation step, an IQ quadrature error may be calculated, and the error correction step may include a quadrature correction step of correcting the IQ quadrature error for the I waveform data and the Q waveform data output in the waveform data output step.

This configuration makes it possible to appropriately correct the IQ quadrature error which is a factor of the image signal in the quadrature modulator and thus to reduce the level of the image signal generated within the quadrature modulation output band.

The calibration method according to the aspect of the present invention may further include a correction value calculation step of defining the calculated IQ quadrature error as α [rad] and calculating a first correction value A and a second correction value B used in the quadrature correction step as A=cos α/cos 2α and B=−tan α, respectively. The quadrature correction step may include a first multiplication step of multiplying the I waveform data by the first correction value A, a second multiplication step of multiplying the Q waveform data by the first correction value A, a third multiplication step of multiplying a multiplication result of the second multiplication step by the second correction value B, a fourth multiplication step of multiplying a multiplication result of the first multiplication step by the second correction value B, a first addition step of adding the multiplication result of the first multiplication step and the multiplication result of the third multiplication step and outputting an addition result as corrected I waveform data, and a second addition step of adding the multiplication result of the second multiplication step and the multiplication result of the fourth multiplication step and outputting an addition result as corrected Q waveform data.

This configuration makes it possible to appropriately correct the IQ quadrature error which is a factor of the image signal in the quadrature modulator and thus to reduce the level of the image signal generated within the quadrature modulation output band.

In the calibration method according to the aspect of the present invention, in the error calculation step, an IQ gain balance may be calculated. Execution of the waveform data output step, the signal analysis step, the error calculation step, and the error correction step may be controlled such that the difference in IF frequency-amplitude characteristics between the I component and the Q component and the difference in IF frequency-phase characteristics between the I component and the Q component are corrected, and fine-tuning correction of the IQ quadrature error and the IQ gain balance may be performed while a level of an image signal is being measured.

In this configuration, the difference in IF frequency-amplitude characteristics between the I component and the Q component and the difference in IF frequency-phase characteristics between the I component and the Q component are appropriately corrected over the entire IF frequency range (coarse adjustment), and then the fine-tuning correction of the IQ quadrature error and the IQ gain balance is performed while the level of the image signal is being measured. Therefore, it is possible to rapidly set the IQ quadrature error and the IQ gain balance to optimal values.

### Advantage of the Invention

According to the aspects of the present invention, it is possible to provide a calibration device and a calibration method for a signal generator that can reduce a level of an image signal generated within a quadrature modulation output band.

### BRIEF DESCRIPTION OF THE DRAWINGS

FIG. 1 is a block diagram showing a configuration of a calibration device for a signal generator according to an embodiment of the present invention.

FIG. 2 is a diagram showing a configuration of calibration signals output to an I channel and a Q channel during calibration.

FIG. 3 is a diagram showing a configuration of a modulated signal captured during calibration.

FIGS. 4A and 4B are diagrams showing an IQ gain balance and an IQ quadrature error.

FIG. 5 is a flowchart showing a calibration method for a signal generator.

### BEST MODE FOR CARRYING OUT THE INVENTION

Hereinafter, embodiments of the present invention will be described with reference to the drawings.

### Configuration

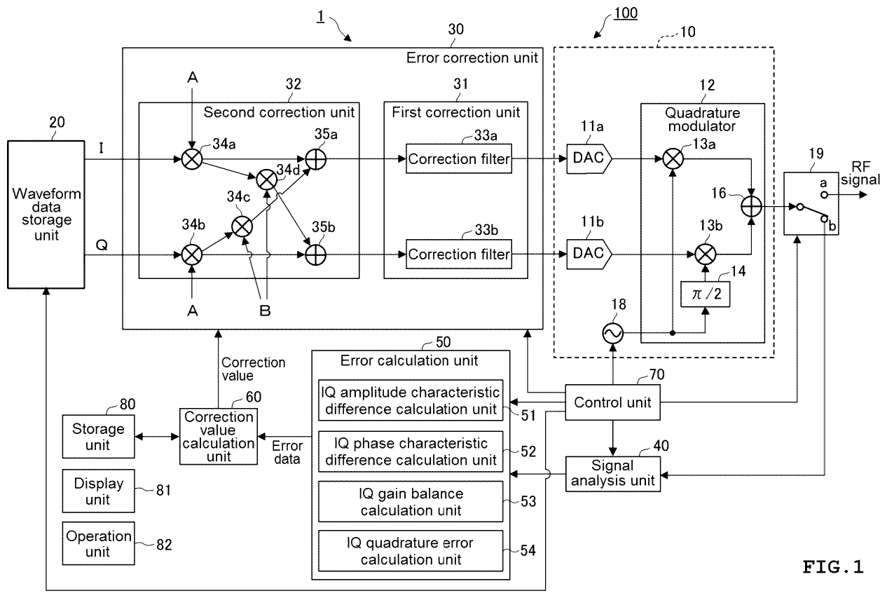

FIG. 1 is a block diagram showing a configuration of a calibration device 1 according to an embodiment of the present invention. As shown in FIG. 1, the calibration device 1 according to the present embodiment calibrates a signal generator 10 and includes a waveform data storage unit 20, an error correction unit 30, a signal analysis unit 40, an error calculation unit 50, a correction value calculation unit 60, a control unit 70, a storage unit 80, a display unit 81, an operation unit 82, and a switch 19. The calibration device 1 and the signal generator 10 constitute a signal generation device 100 with a calibration function.

### <Signal Generator>

The signal generator 10 to be calibrated includes digital-to-analog converters (hereinafter, referred to as “DACs”) 11a and 11b, a quadrature modulator 12, and a local oscillator 18. The quadrature modulator 12 includes multipliers (mixers) 13a and 13b, a 90-degree phase shifter 14, and an adder 16.

The DAC 11a performs D/A conversion of waveform data (hereinafter, referred to as “I waveform data”) of an in-phase component (I component) in a baseband or an IF frequency band into analog waveform data and outputs the analog waveform data to the quadrature modulator 12. The DAC 11b performs D/A conversion of waveform data (hereinafter, referred to as “Q waveform data”) of a quadrature component (Q component) in the baseband or the IF frequency band into analog waveform data and outputs the analog waveform data to the quadrature modulator 12.

The local oscillator 18 generates a carrier signal having a predetermined carrier frequency and outputs the carrier signal to the quadrature modulator 12, under the control of the control unit 70.

In the quadrature modulator 12, the multiplier 13a multiplies the I component signal output from the DAC 11a and the carrier signal output from the local oscillator 18. The multiplier 13b multiplies the Q component signal output from the DAC 11b and the carrier signal whose phase has been shifted by 90 degrees by the 90-degree phase shifter 14. The adder 16 adds the multiplication result of the multiplier 13a and the multiplication result of the multiplier 13b and outputs a modulated signal (RF signal). As described above, the quadrature modulator 12 quadrature-modulates the carrier signal with the analog I waveform data and the analog Q waveform data and outputs the modulated signal.

### <Waveform Data Storage Unit>

The waveform data storage unit 20 stores digital waveform data and stores in advance waveform data (hereinafter, referred to as “test waveform data”) of the I component and the Q component in the baseband or the IF frequency band prepared for testing a device under test (not shown). In addition, the waveform data storage unit 20 stores in advance waveform data (hereinafter, referred to as “calibration waveform data”) of the I component and the Q component in the baseband prepared for calibrating the signal generator 10. The test waveform data and the calibration waveform data are generated by, for example, a digital signal processor (DSP) (not shown).

The waveform data storage unit 20 outputs, as the calibration waveform data, the I waveform data and the Q waveform data at the IF frequency to an I channel and a Q channel, respectively, under the control of the control unit 70 when the signal generator 10 is calibrated.

For example, the waveform data storage unit 20 alternately outputs, as the calibration waveform data, a multi-tone signal obtained by combining two or more tone signals with different IF frequencies to the I channel and the Q channel. While outputting the multi-tone signal to one of the I channel and the Q channel, the waveform data storage unit 20 does not output any signal to the other of the I channel and the Q channel or outputs a zero-value signal to the other channel. Each tone signal is, for example, a sine wave. The calibration waveform data is also referred to as a “single-phase multi-tone signal”.

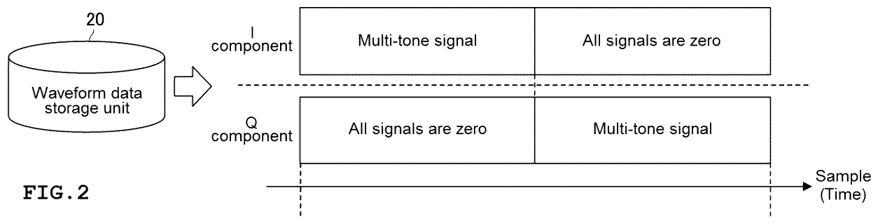

FIG. 2 is a diagram showing a configuration of the calibration waveform data (calibration signal) output from the waveform data storage unit 20 to the I channel and the Q channel during calibration. As shown in FIG. 2, the waveform data storage unit 20 outputs the multi-tone signal to the I channel for a predetermined period of time (for a period of time corresponding to a predetermined number of samples) and then outputs the multi-tone signal to the Q channel for a predetermined period of time (for a period of time corresponding to a predetermined number of samples). While outputting the multi-tone signal to the I channel for a predetermined period of time, the waveform data storage unit 20 outputs the zero-value signal to the Q channel or outputs no signals to the Q channel. On the other hand, while outputting the multi-tone signal to the Q channel for a predetermined period of time, the waveform data storage unit 20 outputs the zero-value signal to the I channel or outputs no signals to the I channel. These signals are also referred to as “I-phase multi-tone” and “Q-phase multi-tone” using the channel on the signal output side.

The calibration waveform data may be appropriately changed depending on correction items (an IQ amplitude characteristic difference, an IQ phase characteristic difference, an IQ quadrature error, an IQ gain balance, and the like) for suppressing an image signal such that the correction items can be easily measured and calculated.

### <Error Correction Unit>

The error correction unit 30 is disposed between the waveform data storage unit 20 and the DACs 11a and 11b and includes a first correction unit 31 and a second correction unit 32. The first correction unit 31 includes an I-phase correction filter 33a and a Q-phase correction filter 33b and corrects a difference in IF frequency-amplitude characteristics between the I component and the Q component and a difference in IF frequency-phase characteristics between the I component and the Q component. The difference in IF frequency-amplitude characteristics between the I component and the Q component and the difference in IF frequency-phase characteristics between the I component and the Q component are mainly caused by a difference between I/Q signal paths from the DACs 11a and 11b to the quadrature modulator 12. The correction filters 33a and 33b are, for example, digital filters such as finite impulse response (FIR) filters. In addition, the first correction unit 31 can also correct the IQ gain balance.

The second correction unit 32 of the error correction unit 30 is also referred to as a quadrature correction unit and corrects an IQ quadrature error for the I waveform data and the Q waveform data output from the waveform data storage unit 20.

Specifically, the second correction unit 32 includes a first multiplier 34a, a second multiplier 34b, a third multiplier 34c, a fourth multiplier 34d, a first adder 35a, and a second adder 35b. The first multiplier 34a multiplies the I waveform data by a first correction value A calculated from the IQ quadrature error by the correction value calculation unit 60. The second multiplier 34b multiplies the Q waveform data by the first correction value A. The third multiplier 34c multiplies the multiplication result of the second multiplier 34b by a second correction value B calculated from the IQ quadrature error by the correction value calculation unit 60. The fourth multiplier 34d multiplies the multiplication result of the first multiplier 34a by the second correction value B. The first adder 35a adds the multiplication result of the first multiplier 34a and the multiplication result of the third multiplier 34c and outputs the addition result as corrected I waveform data. The second adder 35b adds the multiplication result of the second multiplier 34b and the multiplication result of the fourth multiplier 34d and outputs the addition result as corrected Q waveform data.

Here, the first correction value A is calculated as A=cos α/cos 2α, and the second correction value B is calculated as B=−tan α. α [rad] is the IQ quadrature error.

The error correction unit 30 may be configured by, for example, a field programmable gate array (FPGA) or may be implemented by signal processing using software on a computer device.

### <Switch>

The switch 19 is connected to the adder 16 of the quadrature modulator 12 and switches between a test mode and a calibration mode under the control of the control unit 70. In the test mode, the switch 19 is connected to a contact a, and the modulated signal (RF signal), in which the errors causing the image signal have been corrected, is output as the test signal to the device under test. In the calibration mode, the switch 19 is connected to a contact b, and the modulated signal is transmitted to the signal analysis unit 40.

### <Signal Analysis Unit>

The signal analysis unit 40 captures the modulated signal output from the quadrature modulator 12 and quadrature-demodulates the captured modulated signal into I demodulated waveform data and Q demodulated waveform data at the IF frequency. For example, when the above-described single-phase multi-tone signal is used as the calibration waveform data, the signal analysis unit 40 captures the modulated signal output from the quadrature modulator 12 and quadrature-demodulates the captured modulated signal for each of the IF frequencies of the tone signals.

The signal analysis unit 40 can perform, for example, A/D conversion, Fast Fourier Transform (FFT) processing, quadrature demodulation, power measurement, and the like on the modulated signal output from the quadrature modulator 12 as necessary. The signal analysis unit 40 may be configured to include, for example, a vector signal analyzer.

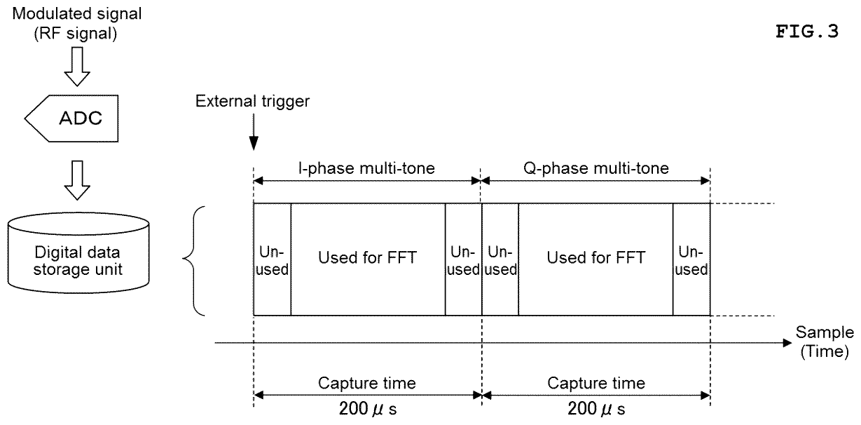

FIG. 3 is a diagram showing a configuration of the modulated signal captured by an analog-to-digital converter (ADC) included in the signal analysis unit 40 during calibration. As shown in FIG. 3, in the data which has been captured by the ADC included in the signal analysis unit 40 and stored in a digital data storage unit, data corresponding to the I-phase multi-tone and data corresponding to the Q-phase multi-tone are alternately disposed. In the example shown in FIG. 3, data captured for a capture time of 200 μs in response to an external trigger signal is the data corresponding to the I-phase multi-tone, and data captured for the next capture time of 200 μs is the data corresponding to the Q-phase multi-tone. In the data corresponding to the I-phase multi-tone, first and last data items having a predetermined length are not used, and the other data is used for FFT processing. The same applies to the data corresponding to the Q-phase multi-tone.

### <Error Calculation Unit>

The error calculation unit 50 includes an IQ amplitude characteristic difference calculation unit 51, an IQ phase characteristic difference calculation unit 52, an IQ gain balance calculation unit 53, and an IQ quadrature error calculation unit 54.

The IQ amplitude characteristic difference calculation unit 51 calculates the difference in IF frequency-amplitude characteristics between the I component and the Q component for the signal generator 10 from the I demodulated waveform data and the Q demodulated waveform data acquired for a plurality of IF frequencies.

The IQ phase characteristic difference calculation unit 52 calculates the difference in IF frequency-phase characteristics between the I component and the Q component for the signal generator 10 from the I demodulated waveform data and the Q demodulated waveform data acquired for a plurality of IF frequencies.

The IQ gain balance calculation unit 53 calculates the IQ gain balance based on the power of the modulated signal obtained by the signal analysis unit 40. Alternatively, the IQ gain balance calculation unit 53 may calculate the IQ gain balance based on the IF frequency-amplitude characteristics calculated by the IQ amplitude characteristic difference calculation unit 51.

The IQ quadrature error calculation unit 54 calculates the IQ quadrature error based on the power of the modulated signal obtained by the signal analysis unit 40.

### <Correction Value Calculation Unit>

The correction value calculation unit 60 calculates a correction value used by the error correction unit 30 to reduce the image signal. For example, the correction value calculation unit 60 calculates the first correction value A and the second correction value B used in the second correction unit 32 of the error correction unit 30 from the IQ quadrature error α [rad] calculated by the IQ quadrature error calculation unit 54 as A=cos α/cos 2α and B=−tan α, respectively.

### <Control Unit>

The control unit 70 is configured by, for example, a computer including a CPU, a ROM, a RAM, and the like and controls the entire calibration device 1 or the entire signal generation device 100 with a calibration function. The control unit 70 controls the operations of, for example, the waveform data storage unit 20, the error correction unit 30, the signal analysis unit 40, the error calculation unit 50, the correction value calculation unit 60, and the switch 19. For example, the control unit 70 outputs a waveform designation signal to the waveform data storage unit 20 to determine the waveform data to be output from the waveform data storage unit 20.

The control unit 70 controls the waveform data storage unit 20, the signal analysis unit 40, the error calculation unit 50, and the error correction unit 30 such that the difference in IF frequency-amplitude characteristics between the I component and the Q component and the difference in IF frequency-phase characteristics between the I component and the Q component are corrected (coarse adjustment) and then causes those units to perform fine-tuning correction of the IQ quadrature error and the IQ gain balance while the signal analysis unit 40 is measuring the level of the image signal (fine adjustment).

The calibration device 1 may include the display unit 81, the operation unit 82, and the storage unit 80.

The display unit 81 is configured as, for example, a display device, such as an LCD or a CRT, and displays various types of display content in response to a control signal from the control unit 70. The display content includes, for example, a list of a plurality of communication standards and a plurality of types of waveform data.

The operation unit 82 is used by the user to perform an input operation and is configured to include an input device such as a keyboard, a touch panel, or a mouse. Alternatively, the operation unit 82 may be configured such that objects to be operated, such as buttons, soft keys, pull-down menus, and text boxes, may be displayed on the display unit 81.

The storage unit 80 stores the error or the correction value calculated by the error calculation unit 50 or the correction value calculation unit 60.

Each of the control unit 70, the signal analysis unit 40, the error calculation unit 50, the correction value calculation unit 60, and the error correction unit 30 may be partially or entirely configured by a computer.

### Factors of Image Signal

The factors of the image signal are the IQ amplitude characteristic difference and the IQ phase characteristic difference occurring between the I/Q signal paths from the DACs 11a and 11b to the quadrature modulator 12, the IQ gain balance error and the IQ quadrature error occurring in the quadrature modulator 12, and the like.

The IQ amplitude characteristic difference is a difference between the I component and the Q component for the frequency-amplitude characteristics in the IF frequency range. The IQ phase characteristic difference is a difference between the I component and the Q component for the frequency-phase characteristics in the IF frequency range.

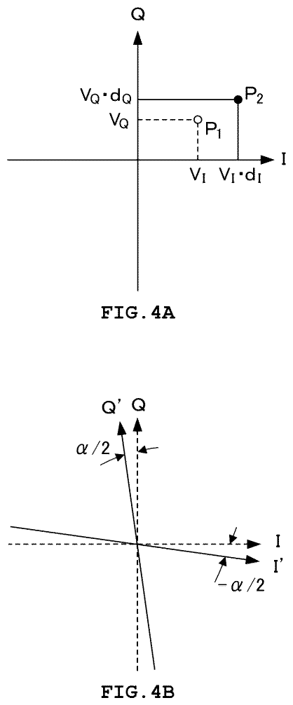

As shown in FIG. 4A, the IQ gain balance error is an error when a signal P1 input to the quadrature modulator 12 is output as a signal P2. Specifically, when the level of the I component of the signal P1 is V_{I}, the level of the Q component of the signal P1 is V_{Q}, the level of the I component of the signal P2 is V_{I}·d_{I}, and the level of the Q component of the signal P2 is V_{Q}·d_{Q} (d_{I}≠d_{Q}), d_{I} and d_{Q} are referred to as the IQ gain balance error. In addition, when d_{I}=d_{Q} is established, that is, when the levels of the I component and the Q component are balanced, there is no particular problem because the levels can be adjusted in a circuit in the subsequent stage.

As shown in FIG. 4B, the IQ quadrature error is an error indicating that an intersection angle between the I-phase axis and the Q-phase axis deviates from π/2 [rad]. For example, when an angle formed by the Q-phase axis with reference to the I-phase axis is (π/2+α) [rad], α is referred to as the quadrature error.

The error calculation unit 50 can measure a power component of the modulated signal output from the quadrature modulator 12 when appropriate calibration waveform data is used, using the signal analysis unit 40, to calculate an I-phase gain balance error d_{I}, a Q-phase gain balance error d_{Q}, and the quadrature error α.

### Calibration Method

Next, a calibration method will be described.

The differences between the I component and the Q component for the frequency-amplitude characteristics and the frequency-phase characteristics over the required IF frequency range (not at one point) in the signal paths from the DACs 11a and 11b to the quadrature modulator 12 are acquired and used as the correction values. In addition, the IQ quadrature error of the quadrature modulator 12 is measured and used as the correction value. Then, the level of the image signal generated in a modulation output band is mainly reduced by two points of eliminating the difference in frequency characteristics (aligning with the frequency characteristics of one phase) over the entire required IF frequency range and reducing the IQ quadrature error.

Specifically, for example, the level of the image signal generated in the modulation output band is reduced by the following correction.

The waveform data input to the DACs 11a and 11b is corrected by an inverse characteristic filter such that the difference in frequency characteristics between the signal paths from the DACs 11a and 11b to the quadrature modulator 12, that is, the difference between the I path and the Q path for each of the IF frequency versus amplitude characteristics and the IF frequency versus phase characteristics, is eliminated (coarse adjustment).

Correction is performed such that the IQ quadrature error of the quadrature modulator 12 is eliminated. For example, the fine tuning of the IQ quadrature error is performed such that the level of the image signal is optimized, and the result of the fine turning is used as the correction value and recorded (fine adjustment).

The difference in frequency characteristics between the I/Q signal paths is corrected before the correction of the IQ quadrature error.

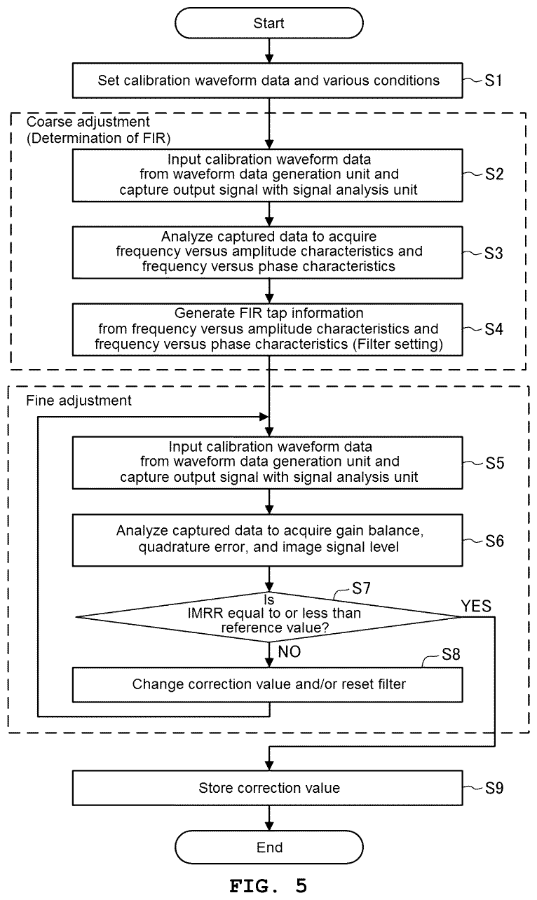

FIG. 5 is a flowchart showing an example of the calibration method.

First, the calibration waveform data and various conditions of the calibration device 1 are set (Step S1).

Specifically, the initial phase of the single-phase multi-tone signal is set such that a peak-to-average power ratio (PAPR) of the signal is minimized. The single-phase multi-tone signal is used for calculating the difference in frequency characteristics between the I/Q signal paths. The multi-tone signals are output from the I-phase DAC 11a and the Q-phase DAC 11b in this order. The time length of the multi-tone signal is, for example, 200 [μs]. A time length that is easy to handle is selected according to an output bandwidth of the signal generator 10 (an analysis bandwidth of the signal analysis unit 40).

For N tone signals constituting the multi-tone signal, an initial phase θₖ [rad] is set by, for example, the following expression.

θₖ=(k(k−1)/(N−1))π, (0≤k≤N−1)

The frequency spacing of the tone signal is set, for example, to 5 [MHz] in a range from 5 MHz to 170 MHz. The frequency spacing directly becomes the interval between frequency points at which the correction values are stored.

Regarding how to select the frequency spacing, considering that the waveform data storage unit 20, which serves as any waveform generator, repeatedly outputs the waveform data, it is preferable that the connection from the end to the beginning of the signal is continuous. On the contrary, when the connection is not continuous, unnecessary waves are generated during the repeated output. In the case of the waveform data having a time length of 200 [μs], when the tone signal has a frequency that is an integer multiple of 1/(200 [μs])=50 kHz (a frequency whose period is an integer division of 200 μs), the connection is continuous even when the waveform data is repeatedly output. For example, the frequency spacing may be intentionally made non-uniform in order to avoid spurious signals caused by hardware during measurement. However, even in this case, it is preferable to select the time length such that the frequency of the tone signal matches a center frequency of an FFT bin in the signal analysis unit 40.

Next, the coarse adjustment is performed. In the coarse adjustment, FIR filters that constitute the correction filters 33a and 33b, respectively, are determined.

The calibration waveform data output from the waveform data storage unit 20 is input to the DACs 11a and 11b, and the modulated signal (RF signal) output from the quadrature modulator 12 is captured or digitized by the signal analysis unit 40 (Step S2). In this case, a trigger signal is output at the beginning of the waveform data to trigger the capture. The calibration waveform data is a single-phase multi-tone signal.

The signal analysis unit 40 performs FFT processing on the captured data. In this case, the FFT processing is performed only on a necessary portion desired to be observed. The signal analysis unit 40 performs quadrature demodulation as necessary to obtain I waveform demodulation data and Q waveform demodulation data at the IF frequency.

Then, the error calculation unit 50 analyzes the data obtained by the signal analysis unit 40 to acquire the IF frequency versus amplitude characteristics and the IF frequency versus phase characteristics (Step S3).

Specifically, the error calculation unit 50 extracts only the frequency points of the multi-tone signal from the results of the FFT processing. Then, the error calculation unit 50 calculates the argument of a complex number corresponding to each frequency point of the multi-tone signal which is the extraction result of each of the I-phase side and the Q-phase side. Since the initial phase of the calibration waveform data is the same for the I component and the Q component, the difference between the calculation results of the arguments is the difference in “IF frequency point versus phase characteristics” between the signal paths. Cycle slip correction is performed on the difference. The inverse characteristic of the calculation result of the cycle slip correction is used as the correction value for the phase characteristics.

In addition, the amplitude is calculated in the same manner on both the I-phase side and the Q-phase side. The reciprocal of the amplitude ratio between the I-phase side and the Q-phase side is used as the correction value for the amplitude characteristics.

Specifically, A(ω_{B}) and Δt(ω_{B}) are obtained as the correction value data.

Here, for a certain IF frequency ω_{B}, A(ω_{B}) and Δt(ω_{B}) indicate a difference in amplitude and a difference in phase (delay time) between the I component and the Q component, respectively. ω_{B} [rad/s] indicates an IF frequency (baseband frequency) expressed as an angular frequency. The difference in frequency characteristics between the I component and the Q component is represented by one complex number of A(ω_{B})exp(−jω_{B}×Δt(ω_{B})). Here, j indicates an imaginary unit.

The difference in characteristics on the negative IF frequency side can also be calculated from the difference in characteristics on the positive IF frequency side. The difference in characteristics on the negative IF frequency side is a conjugate complex number with respect to the difference in frequency characteristics on the positive IF frequency side.

The IF frequency characteristics at a position where the acquisition point and application point of the correction value are different from each other are calculated using interpolation.

Then, the correction value calculation unit 60 generates FIR tap information of the correction filters 33a and 33b, which are FIR filters, from the IF frequency versus amplitude characteristics and the IF frequency versus phase characteristics (Step S4). The FIR filter is applied to the calibration waveform data in the fine adjustment stage.

Specifically, for example, when the frequency characteristics of the FIR filter are measured in 2.5 MHz increments and the frequency points at which the correction value is acquired are in 5 MHz increments, the data of the frequency characteristics at the frequency points at which the correction value is not acquired is calculated by interpolation. In addition, since only the frequency characteristics at the positive IF frequency are measured, the data of the negative IF frequency characteristics required for generating the FIR filter is calculated from the data of the frequency characteristics at the positive IF frequency.

The correction value obtained by the coarse adjustment is applied to set FIR filter coefficients.

Next, the fine adjustment is performed. In the fine adjustment, the IQ quadrature error and the IQ gain balance are corrected.

The calibration waveform data output from the waveform data storage unit 20 is input to the error correction unit 30, and the modulated signal (RF signal) output from the quadrature modulator 12 is captured by the signal analysis unit 40 (Step S5). The calibration waveform data does not need to be a single-phase multi-tone signal, and any waveform data can be used as long as the IQ gain balance, the IQ quadrature error, and the level of the image signal can be acquired.

Then, the error calculation unit 50 analyzes the data of the modulated signal captured by the signal analysis unit 40 to acquire the IQ gain balance, the IQ quadrature error, and the level of the image signal (Step S6).

Then, the control unit 70 compares the IMRR calculated from the level of the image signal with a predetermined reference value. When the IMRR is greater than the reference value (NO in Step S7), the correction value calculation unit 60 changes the correction values and/or resets the correction filters 33a and 33b (Step S8). Then, the process returns to Step S5. The correction values are changed in a direction in which the fine tuning is quickly finished.

When the IMRR is equal to or less than the reference value (YES in Step S7), the current correction values are stored in the storage unit 80 and are set in the error correction unit 30 (Step S9).

The calibration is completed by the above operation.

As described above, in the fine tuning in the fine adjustment, the correction values for the IQ quadrature error and the IQ gain balance are fine-tuned to the optimal values. The error correction unit 30 applies the correction values to the waveform data output from the waveform data storage unit 20, and the signal analysis unit 40 searches for the optimal values while measuring the IMRR.

### <Calculation and Application of FIR Filter Coefficients>

The purpose of applying the correction values in the coarse adjustment is to suppress the difference in frequency characteristics within the IF band in the section from the DACs 11a and 11b to the quadrature modulator 12. Therefore, an FIR filter for canceling the difference from the I-phase signal path may be applied to the Q-phase signal path.

In the stage of calculating the correction value, the difference between the frequency characteristics of the I-phase signal path and the frequency characteristics of the Q-phase signal path is used as the correction value. Therefore, the frequency characteristics used as the basis for the Q-phase FIR filter coefficients may be the inverse characteristics of the value of the correction value data (including interpolation).

The discrete frequency characteristics determined in the above-described process are converted into an impulse response by Inverse Discrete Fourier Transform (IDFT). The sequence is rearranged such that the system becomes a causal system, that is, such that the impulse response starts from time 0. Finally, since the FIR filter is applied only to the Q component, only the real component is extracted. This makes it possible to determine the filter coefficient of the FIR filter of the Q-phase signal path.

On the other hand, for the I-phase signal path, the signal is output with the same delay time as in the Q-phase signal path, without changing the IF frequency-amplitude characteristics. (Since the phase changes by the fixed delay time, the IF frequency-phase characteristics change by an amount corresponding to the change. It is important that the relative values of the I component side and the Q component side and the difference value therebetween are constant with respect to the IF frequency.)

In this case, the IF frequency characteristics of an all-pass filter are converted into an impulse response by IDFT. The sequence is rearranged such that the system becomes a causal system. Therefore, the signal is output with the same delay time as in the Q-phase signal path.

### <Correction Value for Quadrature Error>

When the value of the IQ quadrature error at one IF frequency point is α [rad], the correction value calculation unit 60 calculates the angle correction value A and the angle correction value B as follows.

A=cos α/cos 2α, B=−tan α

In the second correction unit 32 shown in FIG. 1, the angle correction value A is applied to the first multiplier 34a and the second multiplier 34b, and the angle correction value B is applied to the third multiplier 34c and the fourth multiplier 34d. The IQ gain balance can be corrected by changing the filter coefficients of the correction filters 33a and 33b.

### Effect

For example, in the entire band with a bandwidth of 160 MHz (+/−80 MHz), the minimum IMRR in the band is about 34 dB in the related art. However, the minimum IMRR can be increased to about 50 dB by the application of the embodiment of the present invention, which is an improvement of about 16 dB. Therefore, it is possible to generate a high-quality wireless signal and to improve the reliability of, for example, EVM measurement results of the device under test.

### INDUSTRIAL APPLICABILITY

As described above, the present invention has the effect of reducing the level of the image signal generated within the quadrature modulation output band and is useful as a calibration device and a calibration method for a signal generator.

### DESCRIPTION OF REFERENCE NUMERALS AND SIGNS

1: Calibration Device
10: Signal Generator
11a, 11b: D/A Converter (DAC)
12: Quadrature Modulator
13a, 13b: Multiplier (Mixer)
14: 90-Degree Phase Shifter
16: Adder
18: Local Oscillator
19: Switch
20: Waveform Data Storage Unit
30: Error Correction Unit
31: First Correction Unit
32: Second Correction Unit
33a, 33b: Correction Filter
34a, 34b, 34c, 34d: Multiplier
35a, 35b: Adder
40: Signal Analysis Unit
50: Error Calculation Unit
51: IQ Amplitude Characteristic Difference Calculation Unit
52: IQ Phase Characteristic Difference Calculation Unit
53: IQ Gain Balance Calculation Unit
54: IQ Quadrature Error Calculation Unit
60: Correction Value Calculation Unit
70: Control Unit
80: Storage Unit
81: Display Unit
82: Operation Unit
100: Signal Generation Device With Calibration Function

What is claimed is:

1. A calibration device for a signal generator including digital-to-analog (D/A) converters that perform D/A conversion on in-phase (I) waveform data and quadrature-phase (Q) waveform data, respectively, and a quadrature modulator that quadrature-modulates signals subjected to the D/A conversion and outputs the signals as a modulated signal, the calibration device comprising:
a waveform data storage unit that outputs the I waveform data and the Q waveform data at an intermediate frequency (IF frequency) to an I channel and a Q channel, respectively;
a signal analysis unit that captures the modulated signal output from the quadrature modulator and quadrature-demodulates the captured modulated signal into I demodulated waveform data and Q demodulated waveform data at the IF frequency;
an error calculation unit that calculates a difference in IF frequency-amplitude characteristics between an I component and a Q component and a difference in IF frequency-phase characteristics between the I component and the Q component for the signal generator from the I demodulated waveform data and the Q demodulated waveform data acquired for a plurality of the IF frequencies; and
an error correction unit that is disposed between the waveform data storage unit and the D/A converters and includes correction filters correcting the difference in IF frequency-amplitude characteristics between the I component and the Q component and the difference in IF frequency-phase characteristics between the I component and the Q component.

2. The calibration device according to claim 1,
wherein the waveform data storage unit alternately outputs a multi-tone signal obtained by combining two or more tone signals having different IF frequencies to the I channel and the Q channel and, while outputting the multi-tone signal to one of the I channel and the Q channel, does not output any signal to the other of the I channel and the Q channel, and
the signal analysis unit captures the modulated signal output from the quadrature modulator and quadrature-demodulates the captured modulated signal for each of the IF frequencies of the tone signals.

3. The calibration device according to claim 2,
wherein the error calculation unit calculates an IQ quadrature error, and
the error correction unit includes a quadrature correction unit that corrects the IQ quadrature error for the I waveform data and the Q waveform data output from the waveform data storage unit.

4. The calibration device according to claim 3, further comprising:
a correction value calculation unit that defines the calculated IQ quadrature error as α and calculates a first correction value A and a second correction value B used in the quadrature correction unit as A=cos α/cos 2α and B=−tan α, respectively,
wherein the quadrature correction unit includes
a first multiplier that multiplies the I waveform data by the first correction value A,
a second multiplier that multiplies the Q waveform data by the first correction value A,
a third multiplier that multiplies a multiplication result of the second multiplier by the second correction value B,
a fourth multiplier that multiplies a multiplication result of the first multiplier by the second correction value B,
a first adder that adds the multiplication result of the first multiplier and the multiplication result of the third multiplier and outputs an addition result as corrected I waveform data, and
a second adder that adds the multiplication result of the second multiplier and the multiplication result of the fourth multiplier and outputs an addition result as corrected Q waveform data.

5. The calibration device according to claim 4, further comprising:
a control unit,
wherein the error calculation unit calculates an IQ gain balance, and
the control unit controls the waveform data storage unit, the signal analysis unit, the error calculation unit, and the error correction unit such that the difference in IF frequency-amplitude characteristics between the I component and the Q component and the difference in IF frequency-phase characteristics between the I component and the Q component are corrected, and then causes those units to perform fine-tuning correction of the IQ quadrature error and the IQ gain balance while the signal analysis unit is measuring a level of an image signal.

6. A calibration method for a signal generator including digital-to-analog (D/A) converters that perform D/A conversion on in-phase (I) waveform data and quadrature-phase (Q) waveform data, respectively, and a quadrature modulator that quadrature-modulates signals subjected to the D/A conversion and outputs the signals as a modulated signal, the calibration method comprising:
a waveform data output step of outputting the I waveform data and the Q waveform data at an intermediate frequency (IF frequency) to an I channel and a Q channel, respectively;
a signal analysis step of capturing the modulated signal output from the quadrature modulator and quadrature-demodulating the captured modulated signal into I demodulated waveform data and Q demodulated waveform data at the IF frequency;
an error calculation step of calculating a difference in IF frequency-amplitude characteristics between an I component and a Q component and a difference in IF frequency-phase characteristics between the I component and the Q component for the signal generator from the I demodulated waveform data and the Q demodulated waveform data acquired for a plurality of the IF frequencies; and
an error correction step of being executed between the waveform data output step and the D/A conversion by the D/A converter and correcting the difference in IF frequency-amplitude characteristics between the I component and the Q component and the difference in IF frequency-phase characteristics between the I component and the Q component, using correction filters.

7. The calibration method according to claim 6,
wherein, in the waveform data output step, a multi-tone signal obtained by combining two or more tone signals having different IF frequencies is alternately output to the I channel and the Q channel, and, while the multi-tone signal is being output to one of the I channel and the Q channel, no signal is output to the other of the I channel and the Q channel, and
in the signal analysis step, the modulated signal output from the quadrature modulator is captured, and the captured modulated signal is quadrature-demodulated for each of the IF frequencies of the tone signals.

8. The calibration method according to claim 7,
wherein, in the error calculation step, an IQ quadrature error is calculated, and
the error correction step includes a quadrature correction step of correcting the IQ quadrature error for the I waveform data and the Q waveform data output in the waveform data output step.

9. The calibration method according to claim 8, further comprising:
a correction value calculation step of defining the calculated IQ quadrature error as α and calculating a first correction value A and a second correction value B used in the quadrature correction step as A=cos α/cos 2α and B=−tan α, respectively,
wherein the quadrature correction step includes
a first multiplication step of multiplying the I waveform data by the first correction value A,
a second multiplication step of multiplying the Q waveform data by the first correction value A,
a third multiplication step of multiplying a multiplication result of the second multiplication step by the second correction value B,
a fourth multiplication step of multiplying a multiplication result of the first multiplication step by the second correction value B,
a first addition step of adding the multiplication result of the first multiplication step and the multiplication result of the third multiplication step and outputting an addition result as corrected I waveform data, and
a second addition step of adding the multiplication result of the second multiplication step and the multiplication result of the fourth multiplication step and outputting an addition result as corrected Q waveform data.

10. The calibration method according to claim 9,
wherein, in the error calculation step, an IQ gain balance is calculated, and
execution of the waveform data output step, the signal analysis step, the error calculation step, and the error correction step is controlled such that the difference in IF frequency-amplitude characteristics between the I component and the Q component and the difference in IF frequency-phase characteristics between the I component and the Q component are corrected, and fine-tuning correction of the IQ quadrature error and the IQ gain balance is performed while a level of an image signal is being measured.
